(19) United States
(12) Patent Application Publication
(10) Pub. No.: US 2013/0070410 A1
(43) Pub. Date: Mar. 21, 2013

(54) SERIAL ADVANCED TECHNOLOGY ATTACHMENT DUAL IN-LINE MEMORY MODULE AND COMPUTER SYSTEM

(71) Applicants: YUNG-CHIEH CHEN, Tu-Cheng (TW); SHOU-KUO HSU, Tu-Cheng (TW); CHIH-CHUNG SHIH, Tu-Cheng (TW); HSIEN-CHUAN LIANG, Tu-Cheng (TW); WEI-CHIEH CHOU, Tu-Cheng (TW); CHUN-HSIEN TSAI, Tu-Cheng (TW)

(72) Inventors: YUNG-CHIEH CHEN, Tu-Cheng (TW); SHOU-KUO HSU, Tu-Cheng (TW); CHIH-CHUNG SHIH, Tu-Cheng (TW); HSIEN-CHUAN LIANG, Tu-Cheng (TW); WEI-CHIEH CHOU, Tu-Cheng (TW); CHUN-HSIEN TSAI, Tu-Cheng (TW)

(73) Assignee: HON HAI PRECISION INDUSTRY CO., LTD., Tu-Cheng (TW)

(21) Appl. No.: 13/271,803

(22) Filed: Oct. 12, 2011

(30) Foreign Application Priority Data
Sep. 16, 2011 (TW) 100133533

(51) Int. Cl. H05K 7/02

(52) U.S. Cl. 361/679.31

(57) ABSTRACT

A computer system includes a motherboard with first and second storage device interfaces and first to third memory slots, and first to third serial advanced technology attachment dual-in-line memory modules (SATA DIMMs). First and second extending boards are extended from two opposite ends of each SATA DIMM, arranged with first and second edge connectors, respectively. The first edge connector of the first SATA DIMM is connected to the first storage device interface. The second edge connector of the first SATA DIMM is connected to the first edge connector of the second SATA DIMM. The second edge connector of the second SATA DIMM is connected to the first edge connector of the third SATA DIMM. The second edge connector of the third SATA DIMM is connected to the second storage device interface.

### BACKGROUND

1. Technical Field

The present disclosure relates to a serial advanced technology attachment dual in-line memory module (SATA DIMM) and a computer system having the SATA DIMM.

2. Description of Related Art

Solid state drives (SSD) store data on chips instead of magnetic or optical discs as traditional drives. One type of SSD has the form factor of a dual-in-line memory module (DIMM) module and is called a serial advanced technology attachment (SATA) DIMM. As such, the SATA DIMM can be inserted into a memory slot of a motherboard, to receive a voltage from the motherboard through the memory slot. However, hard disk drive (HDD) signals need to be transmitted between the SATA DIMM and the motherboard through a SATA connector set on the SATA DIMM connected to a SATA connector of the motherboard. Moreover, the SATA connector set on the SATA DIMM may occupy a lot of space. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of a serial advanced technology attachment dual in-line memory module (SATA DIMM) in accordance with an exemplary embodiment of the present disclosure.

FIG. 2 is a schematic view of the SATA DIMM of FIG. 1 connected to a motherboard of a computer system.

### DETAILED DESCRIPTION

The disclosure, including the drawings, is illustrated by way of example and not by limitation. References to “an” or “one” embodiment in this disclosure are not necessarily to the same embodiment, and such references mean at least one.

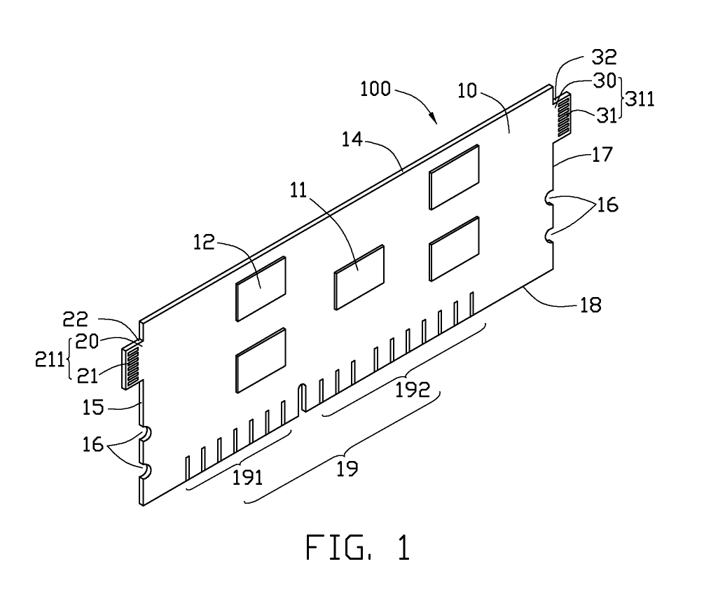

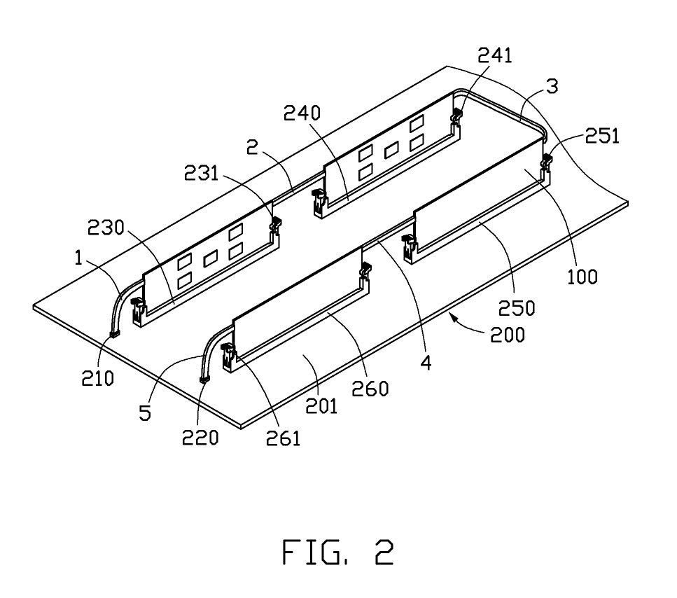

Referring to FIGS. 1 and 2, a serial advanced technology attachment dual-in-line memory module (SATA DIMM) 100 in accordance with an exemplary embodiment includes a substantially rectangular circuit board 10. A control chip 11 and a plurality of storage chips 12 connected to the control chip 11 are arranged on the circuit board 10. An edge connector 19 is arranged on a bottom side 18 of the circuit board 10, to be inserted into a memory slot of a motherboard 200 with a circuit board 201 of a computer system. The edge connector 19 includes a plurality of power pins 191 connected to the control chip 11 and the storage chips 12, and a plurality of ground pins 192 connected to a ground layer (not shown) of the circuit board 10.

First and second storage device connectors 211 and 311 extend from two opposite ends 15 and 17 of the circuit board 10. The first storage device connector 211 includes a first extending board 20 extending from the end 15, and an edge connector 21 arranged on the first extending board 20. The second storage device connector 311 includes a second extending board 30 and an edge connector 31 arranged on the second extending board 30. The edge connectors 21 and 31 are connected to the control chip 11. The control chip 11 receives a control signal from the edge connector 21 and outputs the control signal through the edge connector 31, or receives a control signal from the edge connector 31 and outputs the control signal through the edge connector 21. The control chip 11 stores a control program for controlling the control signal received from the edge connector 21 and output through the edge connector 31 preferentially. Namely, the control chip 11 preferentially outputs the control signal received from the edge connector 21 through the edge connector 31. If the control chip 11 does not receive a control signal from the edge connector 21, the control chip 11 will output the control signal received from the edge connector 31 through the edge connector 21. Two grooves 16 are defined in each of the ends 15 and 17, and located under the first and second extending boards 20 and 30.

Each of the edge connectors 21 and 31 includes a pair of signal input pins, a pair of signal output pins, and three ground pins. The signal input pins and the signal output pins are connected to the control chip 11. The ground pins are connected to a ground layer (not shown) of the circuit board 10.

In one embodiment, the first and second storage device connectors 211 and 311 are in accordance with serial advanced technology attachment (SATA) standard.

Top surfaces 22 and 32 of the first and second extending boards 20 and 30 are lower than a top side 14 of the circuit board 10 opposite to the bottom side 18. When the first and second storage device connectors 211 and 311 are connected to storage device interfaces, top surfaces of the storage device interfaces are lower than or coplanar with the top side 14 of the board 10. Thus, reducing the interference between the SATA DIMM 100 and a chassis (not shown) when the SATA DIMM 100 is mounted on the motherboard 200 accommodated in the chassis.

In one embodiment, four memory slots 230, 240, 250, and 260 and two storage device interfaces 210 and 220 are arranged on the circuit board 201 of the motherboard 200. The storage device interfaces 210 and 220 are SATA connectors.

In assembly, first to fourth SATA DIMMs 100 are respectively inserted into the memory slots 230, 240, 250, and 260 through the edge connectors 19. The grooves 16 of the first to fourth SATA DIMMs 100 are respectively engaged with fixing elements 231, 241, 251, and 261 of the memory slots 230, 240, 250, and 260, to fix the first to fourth SATA DIMMs 100 on the motherboard 200.

The first storage device connector 211 of the first SATA DIMM 100 is connected to the storage device interface 210 through a cable 1 with two interfaces. The second storage device connector 311 of the first SATA DIMM 100 is connected to the first storage device connector 211 of the second SATA DIMM 100 through a cable 2 with two interfaces. The second storage device connector 311 of the second SATA DIMM 100 is connected to the first storage device connector 211 of the third SATA DIMM 100 through a cable 3 with two interfaces. The second storage device connector 311 of the third SATA DIMM 100 is connected to the first storage device connector 211 of the fourth SATA DIMM 100 through a cable 4 with two interfaces. The second storage device connector 311 of the fourth SATA DIMM 100 is connected to the storage device interface 220 through a cable 5 with two interfaces. Namely, the first to fourth SATA DIMMs 100 connected in series.

When the motherboard 200 receives power, the motherboard 200 outputs a voltage to the first to fourth SATA DIMMs 100 through the memory slots 230, 240, 250, and 260 and the edge connectors 19. At the same time, the motherboard 200 outputs a control signal to the control chip 11 of the first SATA DIMM 100 through the storage device interface 210, the cable 1, and the first storage device connector 211 of the first SATA DIMM 100. The control chip 11 of the first SATA DIMM 100 controls the storage chips 12 to store data and transmits the control signal to the control chip 11 of the second SATA DIMM 100 through the second storage device connector 311 of the first SATA DIMM 100, the cable 2, and the first storage device connector 211 of the second SATA DIMM 100. Similarly, the third SATA DIMM 100 receives the control signal from the second SATA DIMM 100, and the fourth SATA DIMM 100 receives the control signal from the third SATA DIMM 100, therefore, the first to fourth SATA DIMMs 100 can communicate with the motherboard 200.

Using the same theory, the motherboard 200 also outputs a control signal to the control chip 11 of the fourth SATA DIMM 100 through the storage device interface 220, the cable 5, and the second storage device connector 311 of the fourth SATA DIMM 100. The control chip 11 of the fourth SATA DIMM 100 controls the storage chips 12 to store data and transmits the control signal to the control chip 11 of the third SATA DIMM 100 through the first storage device connector 211 of the fourth SATA DIMM 100, the cable 4, and the second storage device connector 311 of the third SATA DIMM 100. Similarly, the second SATA DIMM 100 receives the control signal from the third SATA DIMM 100, and the first SATA DIMM 100 receives the control signal from the second SATA DIMM 100, therefore, the first to fourth SATA DIMMs 100 can communicate with the motherboard 200. Namely, when the first to fourth SATA DIMMs 100 of the memory slots 230, 240, 250, and 260 are normal, the first to fourth SATA DIMMs 100 of the memory slots 230, 240, 250, and 260 can receive a control signal from the motherboard 200 through the first storage device connector 211 of the first SATA DIMM 100 and the storage device interface 210, to communicate with the motherboard 200.

If the second SATA DIMM 100 is abnormal, the third and fourth SATA DIMM 100 cannot receive a control signal from the motherboard 200 through the first storage device connector 211 of the first SATA DIMM 100 and the storage device interface 210. Therefore, the control chips 11 of the third and fourth SATA DIMMs 100 need to receive a control signal from the motherboard 200 through the second storage device connector 311 of the fourth SATA DIMM 100 and the storage device interface 220, to communicate with the motherboard 200. When any one of the first to fourth SATA DIMMs 100 is abnormal, other SATA DIMMs 100 can continue working.

The first to fourth SATA DIMMs 100 of the memory slots 230, 240, 250, and 260 can be connected in series through the first and second storage device connectors 211 and 311, to communicate with the motherboard 200. Therefore, the motherboard 200 reduces the number of the storage device interfaces, which are arranged on the motherboard 200.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. A serial advanced technology attachment dual-in-line memory module (SATA DIMM) comprising:
a circuit board;
a control chip arranged on the circuit board;
a plurality of storage chips arranged on the circuit board and connected to the control chip;
a first extending board extending from a first end of the circuit board;
a first edge connector arranged on the first extending board and comprising a pair of first signal input pins, a pair of first signal output pins, and three first ground pins, the first signal input pins and the first signal output pins connected to the control chip;
a second extending board extending from a second end of the circuit board opposite to the first end;
a second edge connector arranged on the second extending board and comprising a pair of second signal input pins, a pair of second signal output pins, and three second ground pins, the second signal input pins and the second signal output pins connected to the control chip; and
a third edge connector set on a bottom side of the board, to be inserted into a memory slot of a motherboard, the third edge connector comprising a plurality of power pins connected to the control chip and the storage chips, and a plurality of third ground pins;
wherein the control chip preferentially outputs a control signal received from the first edge connector through the second edge connector, when the control chip does not receive a control signal from the first edge connector, the control chip outputs a control signal received from the second edge connector through the first edge connector.

2. The SATA DIMM of claim 1, wherein the first and second edge connectors accord with SATA standard.

3. The SATA DIMM of claim 1, wherein top surfaces of the first and second extending boards are lower than a top side of the circuit board opposite to the bottom side.

4. The SATA DIMM of claim 3, wherein two grooves are defined in each of the first and second ends of the circuit board and located below the first and second extending boards, to engage with fixing elements of the memory slot of the motherboard.

5. A computer system comprising:
a motherboard comprising:
a first circuit board;
a first storage device interface mounted on the first circuit board;
a second storage device interface mounted on the first circuit board; and
first to third memory slots mounted on the first circuit board; and
first to third serial advanced technology attachment dual-in-line memory modules (SATA DIMMs), each SATA DIMM comprising:
a second circuit board;
a control chip arranged on the second circuit board;
a plurality of storage chips arranged on the second circuit board and connected to the control chip;
a first extending board extending from a first end of the second circuit board;
a first edge connector arranged on the first extending board and comprising a pair of first signal input pins, a pair of first signal output pins, and three first ground pins, the first signal input pins and the first signal output pins both connected to the control chip;
a second extending board extending from a second end of the second circuit board opposite to the first end;
a second edge connector arranged on the second extending board and comprising a pair of second signal input pins, a pair of second signal output pins, and three second ground pins, the second signal input pins and the second signal output pins both connected to the control chip; and
a third edge connector set on a bottom side of the circuit board, to be inserted into the corresponding one of the first to third memory slots of the motherboard, the third edge connector comprising a plurality of power pins connected to the control chip and the storage chips, and a plurality of third ground pins;
wherein the first edge connector of the first SATA DIMM is connected to the first storage device interface, the second edge connector of the first SATA DIMM is connected to the first edge connector of the second SATA DIMM, the second edge connector of the second SATA DIMM is connected to the first edge connector of the third SATA DIMM, the second edge connector of the third SATA DIMM is connected to the second storage device interface, wherein the control chips of the first to third SATA DIMMs preferentially outputs a control signal received from the first edge connectors through the second edge connectors, when the control chips does not receive a control signal from the first edge connectors, the control chips output a control signal received from the second edge connectors through the first edge connectors.

6. The computer system of claim 5, wherein the first and second edge connectors accord with SATA standard.

7. The computer system of claim 5, wherein top surfaces of the first and second extending boards are lower than a top side of the corresponding second circuit board opposite to the bottom side.

8. The computer system of claim 5, wherein two grooves are defined in each of the first and second ends of each second circuit board and located below the first and second extending boards, to engage with fixing elements of the corresponding memory slot.

9. The computer system of claim 5, wherein the first and second storage device interfaces are SATA connectors.
